(19) United States
(12) Patent Application Publication
(10) Pub. No.: US 2016/0216584 A1
(43) Pub. Date: Jul. 28, 2016

(54) LIQUID CRYSTAL DISPLAY AND MANUFACTURING METHOD THEREOF

(71) Applicant: Samsung Display Co., Ltd., Yongin-City (KR)

(72) Inventors: Keum Hee LEE, Goyang-si (KR); Young Joo CHOI, Suwon-si (KR)

(21) Appl. No.: 14/805,237

(22) Filed: Jul. 21, 2015

(30) Foreign Application Priority Data
Jan. 26, 2015 (KR) 10-2015-0012142
Jun. 8, 2015 (KR) 10-2015-0080379

(51) Int. Cl. G02F 1/1362; G02F 1/1343; H01L 27/12; G02F 1/1368

(52) U.S. Cl. CPC G02F 1/136286; G02F 1/1368; G02F 1/13439; H01L 27/1259; H01L 27/1225; H01L 27/1248; G02F 2001/136295

(57) ABSTRACT

A liquid crystal display and a manufacturing method thereof are disclosed, whereby a common electrode having a planar shape is formed directly on a common voltage line, and a semiconductor layer is formed on the common electrode and a gate line. The common electrode and a pixel electrode are formed on one substrate, with the common electrode being formed directly on the common voltage line. Accordingly, the costs of manufacturing the liquid crystal display may be reduced, and signal delay of a common voltage can be prevented.

### CROSS-REFERENCE TO RELATED APPLICATION

This application claims priority to and the benefit of Korean Patent Application No. 10-2015-0012142 filed in the Korean Intellectual Property Office on Jan. 26, 2015 and Korean Patent Application No. 10-2015-0080379 filed in the Korean Intellectual Property Office on Jun. 8, 2015, the entire contents of which are incorporated herein by reference.

### BACKGROUND

(a) Technical Field

The present disclosure generally relates to a liquid crystal display and a method of manufacturing the same.

(b) Description of the Related Art

A liquid crystal display is one type of flat panel display that is widely used. The liquid crystal display is a display device that can adjust an amount of transmitted light, by applying a voltage to electrodes disposed in the display device so as to rearrange liquid crystal molecules of a liquid crystal layer.

An advantage of the liquid crystal display is that it can be easily thinned. However, a drawback of the liquid crystal display is that it has lower side visibility than front visibility. To mitigate the above drawback, different methods of arranging and driving a liquid crystal have been developed. In one method, a liquid crystal display having a pixel electrode and a common electrode that are formed on a single substrate is provided in order to implement a wide viewing angle. In the aforementioned liquid crystal display, a common voltage line for transferring the common voltage is formed to prevent signal delays of the common voltage.

However, different optical masks may be required to form the common voltage line, the pixel electrode, and the common electrode on a single substrate, and to form other regions including electrodes such as a direct connecting part of a pixel and the like. As a result, the costs of manufacturing the liquid crystal display may increase.

The information disclosed in this Background section is to enhance understanding of the background of the inventive concept and therefore it may contain information that does not form the prior art that is already known in this country to a person of ordinary skill in the art.

### SUMMARY

The present disclosure addresses at least the above issues, by providing a liquid crystal display and a manufacturing method thereof, whereby two electric field generating electrodes may be formed without requiring an additional optical mask process, and whereby a direct connecting part of a pixel may be formed at the same time as the field generating electrodes. Accordingly, the costs of manufacturing the exemplary liquid crystal display can be reduced.

According to an exemplary embodiment of the inventive concept, a liquid crystal display is provided. The liquid crystal display includes: a substrate; a gate line and a pixel electrode formed on the substrate; a semiconductor layer formed on the gate line; and a data line, a source electrode, and a drain electrode formed on the semiconductor layer, wherein the drain electrode is formed overlapping with a first portion of the pixel electrode, wherein the first portion of the pixel electrode includes a first layer formed of poly indium tungsten oxide (poly-ITO) and a second layer formed of a metal, and wherein other portions of the pixel electrode excluding the first portion include the first layer and does not include the second layer.

In some embodiments, the liquid crystal display may further include: a direct connecting part including a gate electrode formed of a same material as the gate line; a gate insulating layer formed on a portion of the gate electrode; and a contact electrode formed on the gate electrode and the gate insulating layer.

In some embodiments, the contact electrode may be in contact with the portion of the gate electrode so as to transfer a gate signal from a driving part to the gate electrode.

In some embodiments, each of the gate line and the gate electrode may include a first layer formed of amorphous indium tungsten oxide (a-ITO) and a second layer formed of a metal.

In some embodiments, the liquid crystal display may further include a passivation layer formed on the source electrode, the drain electrode, and a pixel area; and a common electrode formed on the passivation layer.

In some embodiments, the common electrode may include a plurality of branch electrodes.

According to another embodiment of the inventive concept, a method of manufacturing a liquid crystal display is provided. The method includes: forming a gate line and a first pixel electrode on a substrate; forming a gate insulating layer on the gate line and converting the first pixel electrode to a second pixel electrode; and forming a data line, a source electrode, and a drain electrode on the gate insulating layer, wherein the drain electrode is formed overlapping with a first portion of the second pixel electrode, and wherein a first layer of the first pixel electrode is formed of amorphous indium tungsten oxide (a-ITO) and a first layer of the second pixel electrode is formed of poly indium tungsten oxide (poly-ITO).

In some embodiments, converting the first pixel electrode to the second pixel electrode may further include: stacking the gate insulating layer on the gate line and the first pixel electrode using a high temperature deposition process; and etching the gate insulating layer that is stacked on the first pixel electrode, wherein the first layer of the first pixel electrode may be converted to the first layer of the second pixel electrode during the stacking of the gate insulating layer.

In some embodiments, forming the drain electrode may include: stacking an electrode layer on the gate insulating layer and the second pixel electrode; and patterning the electrode layer, wherein patterning the electrode layer may include etching portions of the electrode layer other than the first portion of the second pixel electrode.

In some embodiments, the first portion of the second pixel electrode may include a second layer formed of a metal.

In some embodiments, the method may further include: forming a passivation layer on the source electrode, the drain electrode, and a pixel area; and forming a common electrode on the passivation layer.

In some embodiments, forming the common electrode may include forming a plurality of branch electrodes.

### BRIEF DESCRIPTION OF THE DRAWINGS

FIG. 1 is a layout view of a liquid crystal display according to an exemplary embodiment.

FIG. 2 is a cross-sectional view taken along line II-II of the liquid crystal display of FIG. 1.

FIG. 3 is a cross-sectional view taken along line III-III of the liquid crystal display of FIG. 1.

FIGS. 4, 7, 10, and 13 are layout views sequentially illustrating a method of manufacturing a liquid crystal display according to an exemplary embodiment.

FIGS. 5, 8, 11, and 14 are cross-sectional views taken along line II-II of FIG. 1 sequentially illustrating the method of manufacturing the liquid crystal display according to the exemplary embodiment.

FIGS. 6, 9, 12, and 15 are cross-sectional views taken along line III-III of FIG. 1 sequentially illustrating the method of manufacturing the liquid crystal display according to the exemplary embodiment.

### DETAILED DESCRIPTION

The inventive concept will be described more fully herein with reference to the accompanying drawings, in which exemplary embodiments are shown. As those skilled in the art would realize, the embodiments may be modified in various ways without departing from the spirit or scope of the present disclosure.

In the drawings, the thickness of layers, films, panels, regions, etc., may be exaggerated for clarity. Like reference numerals designate like elements throughout the specification. It will be understood that when an element such as a layer, film, region, or substrate is referred to as being “on” another element, it can be directly on the other element, or with one or more intervening elements being present. In contrast, when an element is referred to as being “directly on” another element, there are no intervening elements present.

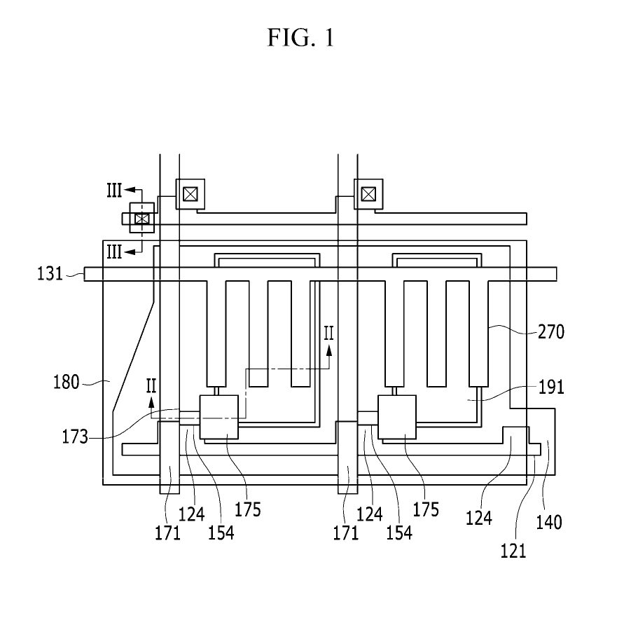

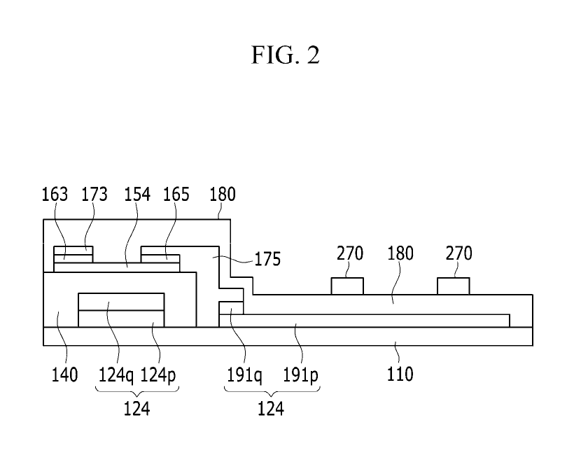

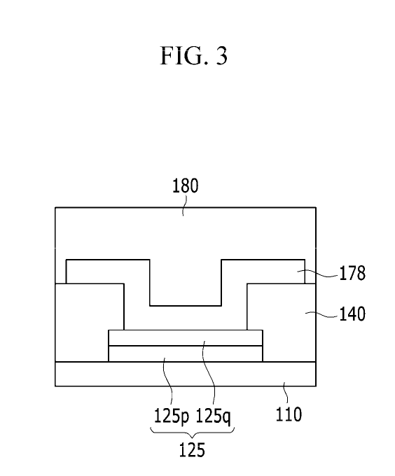

First, a liquid crystal display according to an exemplary embodiment will be described with reference to FIGS. 1 to 3. FIG. 1 is a layout view of the liquid crystal display according to the exemplary embodiment, FIG. 2 is a cross-sectional view taken along line II-II of the liquid crystal display of FIG. 1, and FIG. 3 is a cross-sectional view taken along line III-III of the liquid crystal display of FIG. 1.

The exemplary liquid crystal display includes a first display panel and a second display panel disposed facing each other, and a liquid crystal layer interposed between the first display panel and the second display panel.

Referring to FIGS. 1 to 3, firstly, the first display panel will be described as follows.

A plurality of gate lines 121 and common voltage lines 131 are formed on a first substrate 110.

Each gate line 121 includes a plurality of gate electrodes 124. In some embodiments, the gate electrode 124 may be formed having two layers. For example, the gate electrode 124 may include a transparent electrode layer 124p made of amorphous indium tungsten oxide (a-ITO) or the like, and a metal layer 124q made of copper (Cu) or the like. In addition, a pixel electrode 191 is formed on the same layer as the gate electrode 124 in a pixel area. The pixel electrode 191p may be made of a transparent electrode material such as poly ITO or the like. In some embodiments, the pixel electrode 191p may be initially made of a transparent electrode material such as amorphous ITO or the like, and then converted to poly ITO by a high temperature process. A gate electrode 125 of a direct connecting part formed on the same layer as the gate electrode 124. The gate electrode 125 of the direct connecting part may include a transparent electrode layer 125p such as a-ITO or the like, and a metal layer 125q made of copper or the like, similar to the plurality of gate electrodes 124.

A gate insulating layer 140 is formed on the gate electrode 124 and the gate electrode 125 of the direct connecting part.

A semiconductor layer 154 is formed on the gate insulating layer 140.

Ohmic contacts 163 and 165 are formed on the semiconductor layer 154. A data line 171, a source electrode 173, and a drain electrode 175 are formed on the ohmic contacts 163 and 165.

The data line 171 transfers a data signal and extends in a substantially vertical direction so as to intersect with the gate line 121.

A passivation layer 180 is formed on the semiconductor layer 154, the data line 171, the source electrode 173, the drain electrode 175, and the pixel electrode 191.

The common voltage lines 131 and a plurality of common electrodes 270 are formed on the passivation layer 180. The common voltage lines 131 are connected across the plurality of pixel areas so as to apply a common voltage to the common electrodes 270 disposed in the plurality of pixels. The common electrodes 270 include a plurality of branch electrodes, and the pixel electrode 191 is formed having a planar shape. The pixel electrode 191 overlaps with the plurality of branch electrodes of the common electrodes 270 with the passivation layer 180 disposed therebetween.

The data voltage is applied to the pixel electrode 191 and the common voltage is applied to the common electrode 270, so as to generate an electric field in the liquid crystal layer. The electric field determines the direction of the liquid crystal molecules of the liquid crystal layer, which enables a corresponding image to be displayed.

A first alignment layer is coated on an inner surface of the first display panel.

Next, the second display panel will be described. The second display panel includes a second substrate. A second alignment layer is coated on an inner surface of the second substrate.

The first alignment layer and the second alignment layer may be horizontal alignment layers.

The liquid crystal layer is interposed between the first display panel and the second display panel, and may include a plurality of liquid crystal molecules. The liquid crystal molecules of the liquid crystal layer may be aligned so that long axes thereof are parallel to the surfaces of the two display panels and in the absence of an electric field.

A backlight generates and provides light to the two display panels. In some embodiments, the backlight may be disposed on an outer portion of the substrate of the first display panel.

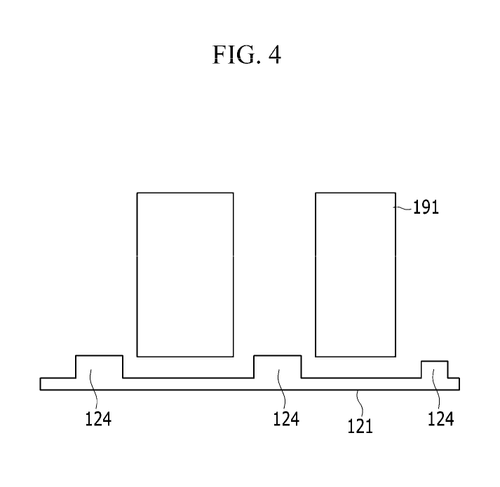

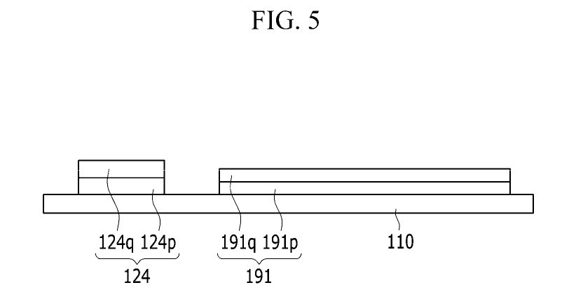

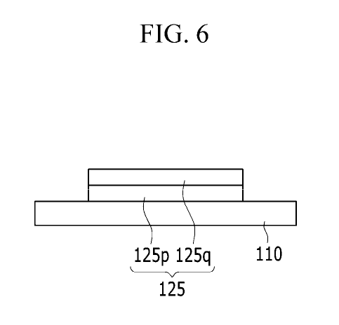

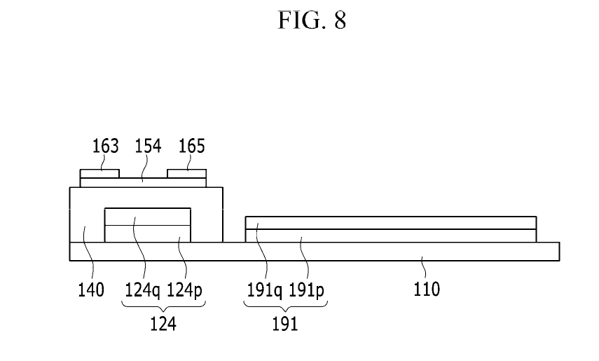

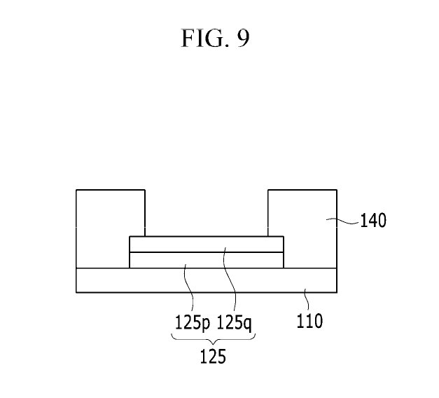

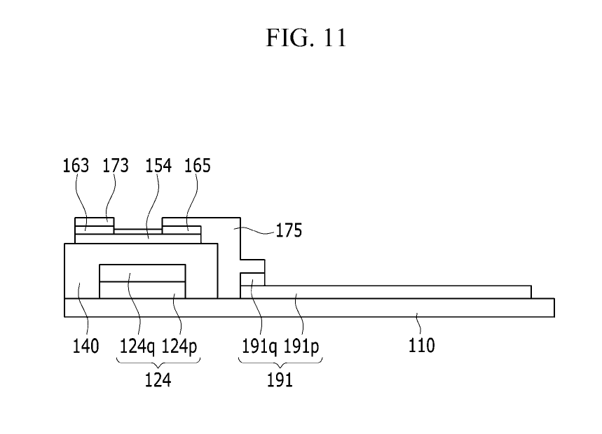

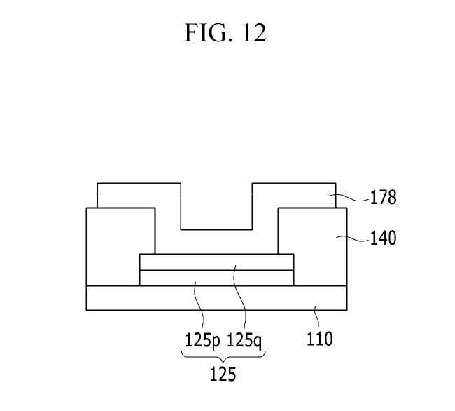

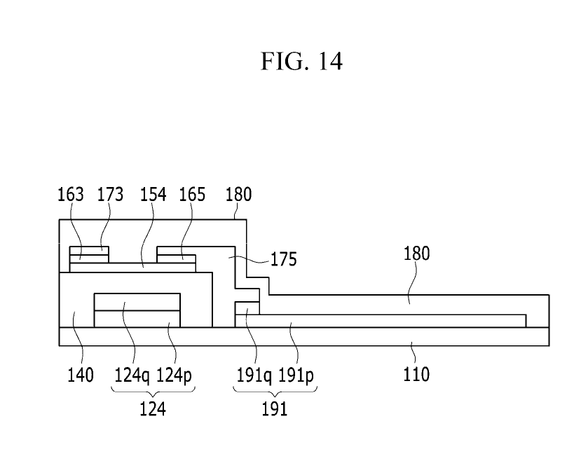

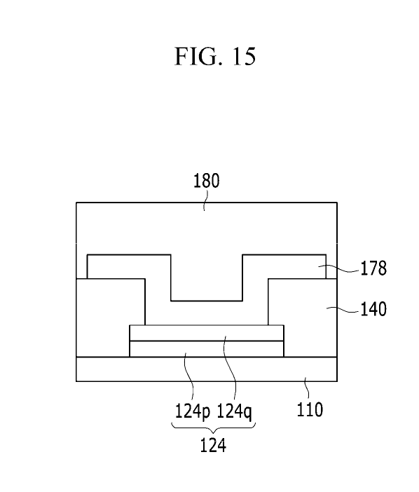

Next, a method of manufacturing a liquid crystal display according to an exemplary embodiment will be described with reference to FIGS. 4 to 15, together with FIGS. 1 to 3. Specifically, FIGS. 4, 7, 10, and 13 are layout views sequentially illustrating the method of manufacturing the liquid crystal display according to the exemplary embodiment; FIGS. 5, 8, 11, and 14 are cross-sectional views taken along line II-II of FIG. 1 sequentially illustrating the method of manufacturing the liquid crystal display according to the exemplary embodiment; and FIGS. 6, 9, 12, and 15 are cross-sectional views taken along line III-III of FIG. 1 sequentially illustrating the method of manufacturing the liquid crystal display according to the exemplary embodiment.

As shown in FIGS. 4 to 6, a gate line 121, a gate electrode 124, a pixel electrode 191, and a gate electrode 125 of a direct connecting part are first formed on a first substrate 110 by using a first mask. The gate line 121, the gate electrode 124, the pixel electrode 191, and the gate electrode 125 are simultaneously formed with the same material and are etched by using the first mask. The first mask may be a type of full-tone mask. The gate line 121, the gate electrode 124 of the thin film transistor, the pixel electrode 191, and the gate electrode 125 of the direct connecting part may be formed having two layers. A first layer 124p, 125p, and 191p may be formed of a transparent electrode material such as a-ITO, and a second layer 124q, 125q, and 191q disposed on the first layer may be formed of a metal such as copper.

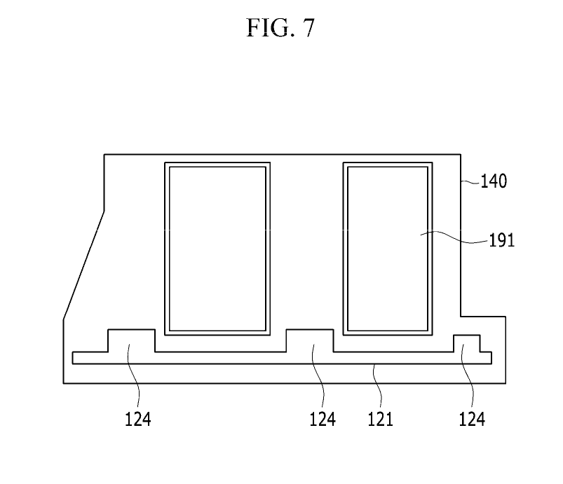

Referring to FIGS. 7 to 9, a gate insulating layer 140, a semiconductor layer 154, and ohmic contacts 163 and 165 are formed. In the above embodiment, portions of the gate insulating layer 140, the semiconductor layer 154, and the ohmic contacts layer 163 and 165 are patterned by using a second mask. The second mask may be a type of half-tone mask. A photoresist (not shown) formed by using the second mask in a photolithography process may have thick portions disposed on the ohmic contacts 163, 165, thin portions disposed on the semiconductor layer 154, and opening portions disposed on the pixel electrode 191. In some embodiments, the a-ITO of the first layer 124p, 125p, and 191p may be converted to poly ITO by a high temperature process (such as a chemical vapor deposition (CVD) or the like) used in the formation of the gate insulating layer 140. As a result, the poly ITO remains during the patterning of the source electrode 173 and the drain electrode 175.

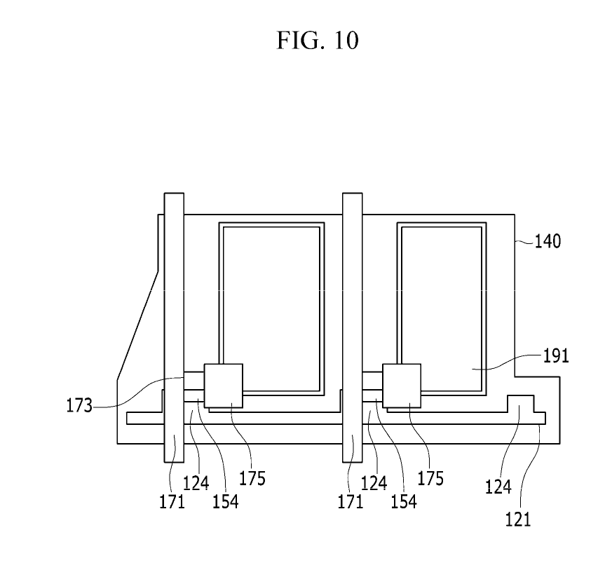

As shown in FIGS. 10 to 12, a data line 171, a source electrode 173, and a drain electrode 175 are formed by using a third mask. The third mask may be a type of full-tone mask. In some embodiments, the drain electrode 175 extends covering a portion of the second layer 191q of the pixel electrode 191. Thereafter, a portion that is not covered by the drain electrode 175 in the second layer 191q of the pixel electrode 191 is removed during the patterning. As a result, only the first layer 191p that is converted to the poly ITO is left remaining, and serves as the pixel electrode. According to the present invention, an issue relating to protrusion of a semiconductor layer 154 may be resolved. If there is protrusion of the semiconductor layer 154, undesired photocurrent may be generated by the light of the backlight. In the present invention, there is no protrusion of the semiconductor layer 154, as the semiconductor layer 154 is etched by using the second mask and then the source and drain electrodes 173, 175 are etched independently by using the third mask. Additionally, this may also resolve another issue relating to a critical dimension (CD) of the source and drain electrodes 173 and 175.

A contact electrode 178 of the direct connecting part is also formed together with the data line 171, the source electrode 173, and the drain electrode 175. Since the portion of the gate insulating layer 140 disposed on the gate electrode 125 of the direct connecting part is removed when the gate insulating layer 140 is formed, a portion of the contact electrode 178 will therefore be in contact with the portion of the gate electrode 125, so that the contact electrode 178 may transfer a gate signal from a driving part to the gate electrode 125.

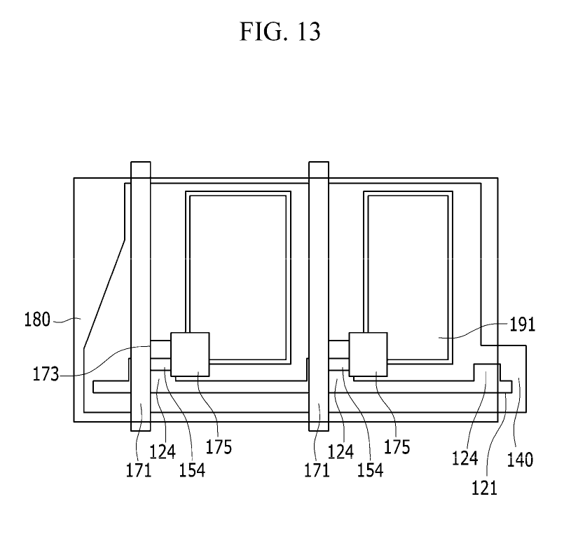

Next, as shown in FIGS. 13 to 15, a passivation layer 180 is formed on the semiconductor layer 154, the data line 171, the source electrode 173, the drain electrode 175, and the pixel electrode 191. The passivation layer 180 is etched by using a fourth mask to open pad parts. The fourth mask may be a type of full-tone mask.

Next, as shown in FIGS. 1 to 3, a common voltage line 131 and a common electrode 270 are formed by using a fifth mask. The fifth mask may be a type of full-tone mask. The common electrode 270 is formed on the pixel electrode 191, and may include a plurality of branches extending in a vertical direction.

According to one or more of the above-described embodiments, the number of mask processes may be reduced by simultaneously forming the direct connecting part with the thin film transistor and the pixel area, and the drain electrode is formed extending and connected to the pixel electrode. Accordingly, the costs of manufacturing the liquid crystal display may be reduced, and the reliability of the connections between the electrodes may be improved.

While the inventive concept has been described in connection with what are presently considered to be exemplary embodiments, it is to be understood that the inventive concept is not limited to the disclosed embodiments, but, on the contrary, is intended to cover various modifications and equivalent arrangements included within the spirit and scope of the appended claims.

1. A liquid crystal display comprising:
a substrate;
a gate line and a pixel electrode formed on the substrate, the pixel electrode having a single-layered portion including a first layer and a double-layered portion including the first layer and a second layer;
a semiconductor layer formed on the gate line; and
a data line, a source electrode, and a drain electrode formed on the semiconductor layer,
wherein the drain electrode is formed on an upper surface of the double-layered portion of the pixel electrode,
wherein the first layer of the pixel electrode is formed of poly indium tungsten oxide (poly-ITO) and the second layer of the pixel electrode is formed of a metal.

2. The liquid crystal display of claim 1, further comprising:
a direct connecting part including a gate electrode formed of a same material as the gate line;
a gate insulating layer formed on a portion of the gate electrode; and
a contact electrode formed on the gate electrode and the gate insulating layer.

3. The liquid crystal display of claim 2, wherein the contact electrode is in contact with the portion of the gate electrode so as to transfer a gate signal from a driving part to the gate electrode.

4. The liquid crystal display of claim 2, wherein each of the gate line and the gate electrode includes a first layer formed of amorphous indium tungsten oxide (a-ITO) and a second layer formed of the metal.

5. The liquid crystal display of claim 1, further comprising:
a passivation layer formed on the source electrode, the drain electrode, and a pixel area; and
a common electrode formed on the passivation layer.

6. The liquid crystal display of claim 5, wherein the common electrode includes a plurality of branch electrodes.

7. A method of manufacturing a liquid crystal display, comprising:
forming a gate line, a first layer of a pixel electrode, and a second layer of the pixel electrode on a substrate, wherein the first layer of the pixel electrode is formed of amorphous indium tungsten oxide (a-ITO) and the second layer of the pixel electrode is formed of a metal;
forming a gate insulating layer on the gate line and converting the a-ITO of the first layer of the pixel electrode to poly indium tungsten oxide (poly ITO);
forming a data line, a source electrode, and a drain electrode on the gate insulating layer, and
etching the second layer of the pixel electrode except a part of the second layer on a partial edge portion of the first layer of the pixel electrode,
wherein the drain electrode is formed on the part of the second layer of the pixel electrode.

8. The method of claim 7, further includes:
stacking the gate insulating layer on the gate line and the second layer of the pixel electrode using a high temperature deposition process, and
etching the gate insulating layer that is stacked on the second layer of the pixel electrode,
wherein the first layer of the first pixel electrode is converted to a layer of the poly-ITO during the stacking of the gate insulating layer.

9. The method of claim 8, wherein forming the drain electrode includes:
stacking the second layer of the pixel electrode on the first layer of the pixel electrode; and
patterning the second layer of the pixel electrode by etching the second layer of the pixel electrode other than the partial edge portion of the pixel electrode.

10. The method of claim 9, wherein the drain electrode overlaps the partial edge portion of the pixel electrode that includes the first layer and the second layer.

11. The method of claim 7, further comprising:
forming a passivation layer on the source electrode, the drain electrode, and a pixel area; and
forming a common electrode on the passivation layer.

12. The method of claim 11, wherein forming the common electrode includes forming a plurality of branch electrodes.
